(19) United States
(12) Patent Application Publication
(10) Pub. No.: US 2021/0254237 A1
(43) Pub. Date: Aug. 19, 2021

(54) SYNTHESIS OF SINGLE CRYSTAL FILMS ON AMORPHOUS SUBSTRATES

(71) Applicant: Jagannathan Rajagopalan, Tempe, AZ (US)

(72) Inventor: Jagannathan Rajagopalan, Tempe, AZ (US)

(21) Appl. No.: 17/176,584

(22) Filed: Feb. 16, 2021

Related U.S. Application Data
(60) Provisional application No. 62/978,419, filed on Feb. 19, 2020.

(51) Int. Cl. C30B 23/06; C30B 29/52

(52) U.S. Cl. CPC C30B 23/063; C30B 29/52; C30B 23/06

(57) ABSTRACT

Forming a single crystal film includes contacting a seed crystal with one or more amorphous metallic alloy layers to form an amorphous precursor film, and annealing the amorphous precursor film to yield the single crystal film.

### CROSS-REFERENCE TO RELATED APPLICATION

This application claims the benefit of U.S. Patent Application No. 62/978,419 entitled “SYNTHESIS OF SINGLE CRYSTAL FILMS ON AMORPHOUS SUBSTRATES” and filed on Feb. 19, 2020, which is incorporated by reference herein in its entirety.

### TECHNICAL FIELD

This invention relates to synthesis of single crystal films on amorphous substrates by crystallization of amorphous precursor films embedded with a seed crystal.

### BACKGROUND

Single crystals of metals, ceramics and semiconductors often possess superior mechanical, optical, catalytic and electronic properties compared to their polycrystalline counterparts. But for a few exceptions (e.g., Si, Ge, Ni-based superalloys), most materials are used in their polycrystalline form because single crystals are both difficult and expensive to synthesize.

Conventionally, single crystal ingots of metals have been produced by the Bridgman or Czochralski process via solidification from the melt, which requires very high processing temperatures. Single crystal metallic sheets and bars have been fabricated from commercial polycrystalline foils/bars by contact free annealing and thermal cycling, respectively. However, these processes typically require annealing temperatures approaching the melting temperature (Tₘ) of the material or exploit phase transformations that are unique to a particular material, which cannot be replicated in other material systems.

Single crystal metallic films, which have potential applications in electronics, optics, thermal barrier coatings and microelectromechanical systems (MEMS) based sensors/actuators, can be synthesized by epitaxial or heteroepitaxial growth on single crystal substrates that have a high degree of lattice matching with the film. This technique, however, suffers from drawbacks, including the limited number of usable substrates and the stringent conditions that need to be satisfied for epitaxial growth, which severely restricts the choice of materials. In many applications, metallic films need to be deposited on amorphous or polycrystalline substrates, which preclude the use of epitaxial or heteroepitaxial growth. While single crystal and very large grained Au and Ag films have been synthesized on amorphous substrates by liquid phase epitaxy and oxygen-induced grain growth, respectively, these processes typically require very high temperatures (exceeding Tₘ of the metal) or involve incorporation of impurities that may compromise the properties of the film.

### SUMMARY

This disclosure describes synthesis of single crystal films on amorphous substrates by crystallization of amorphous films embedded with a seed crystal. By identifying appropriate seed crystals, the method can be applied to any metallic alloy (dilute alloys, intermetallic alloys, high entropy alloys) that can be grown as an amorphous film.

The synthesis process includes growing amorphous metallic alloy layer(s) of desired thickness by physical vapor deposition (e.g., by magnetron sputtering). A single seed crystal is formed by depositing the seed material at an appropriate temperature and rate through a patterned mask with a nanometer-sized hole. The seed crystal can be encapsulated by the substrate and an amorphous alloy layer or by two amorphous alloy layers. It can also be deposited on top of an amorphous alloy layer. The seed crystal along with the amorphous layer(s) comprise the precursor film. The precursor film is then crystallized by annealing to obtain the single crystal film. This seeding technique allows nucleation of a single grain in the precursor film, which grows to consume the film and form a single crystal in a solid to solid (amorphous to crystalline) transformation, which typically requires much lower temperatures than liquid to solid transformation processes. The processing temperatures are relatively low (0.4-0.6 times the melting temperature of the metallic alloy or lower). Moreover, unlike epitaxial or heteroepitaxial growth methods, methods described in this disclosure do not require single crystal substrates.

A general aspect relates to forming a single crystal film by contacting a seed crystal with one or more amorphous metallic alloy layers to form an amorphous precursor film, and annealing the amorphous precursor film to yield the single crystal film.

Implementations of the general aspect may include one or more of the following features.

Contacting the seed crystal with the one or more amorphous metallic alloy layers can include disposing the seed crystal on one of the one or more amorphous metallic alloy layers, disposing one of the one or more amorphous metallic alloy layers on the seed crystal, or encapsulating the seed crystal between the amorphous metallic alloy layers. Contacting the seed crystal with the one or more amorphous metallic alloy layers can include contacting a single seed crystal with the one or more amorphous metallic alloy layers. In some cases, contacting the seed crystal with the one or more amorphous metallic alloy layers includes sputtering the seed crystal through a patterned mask with a nanometer-sized opening.

Forming the one or more amorphous metallic alloy layers can include co-depositing (e.g., sputtering) constituent elements of the metallic alloy.

In some cases, at least one of the one or more amorphous metallic alloy layers can include TiAl. When at least one of the one or more amorphous metallic alloy layers include TiAl, the seed crystal can include one or more of Ti, Al, TiAl and Ag. Crystallization of amorphous TiAl can lead to the formation of γ-TiAl.

In certain cases, at least one of the one or more amorphous metallic alloy layers can include NiTi. When at least one of the one or more amorphous metallic alloy layers include NiTi, the crystallization of amorphous NiTi leads to the formation of austenitic NiTi. When at least one of the one or more amorphous metallic alloy layers include NiTi, the seed crystal includes one or more of NiTi, Cu, Cr, Fe, W, Nb and V.

The seed crystal typically has a misfit strain (εₘ) with the amorphous metallic alloy layer of less than 10%. The seed crystal can lower the crystallization temperature of the one or more amorphous metallic alloy layers.

Some implementations of the general aspect include forming at least one of the one or more amorphous metallic alloy layer at room temperature.

Annealing the amorphous precursor film can include heating the amorphous precursor film below 0.6 Tₘ, where Tₘ represents the melting temperature of at least one of the one or more amorphous metallic alloy layers.

Single crystal films have applications in photovoltaics (e.g., transparent conducting oxide films), electronics (e.g., Cu, Ag and Co films), optoelectronics (e.g. indium tin oxide films), MEMS actuators and sensors (NiTi films), protective coatings for high temperature structural alloys (TiAl and NiAl films) and solid state thermal energy storage (NiTi films).

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1 is a flow chart including operations in a first process for synthesizing a single crystal film by crystallization of amorphous precursor films embedded with a seed crystal.

FIG. 2 is a flow chart including operations in a second process for synthesizing a single crystal film by crystallization of amorphous precursor films embedded with a seed crystal.

FIG. 3 is a flow chart including operations in a second process for synthesizing a single crystal film by crystallization of amorphous precursor films embedded with a seed crystal.

FIG. 4A shows a bright-field transmission electron microscopy (TEM) image of an amorphous TiAl film. The diffuse ring in the selected area electron diffraction pattern (inset) confirms the amorphous nature of the film. FIG. 4B shows a bright-field TEM image of a TiAl film embedded with Ti seed crystals. The Ti seeds formed spontaneously on deposition of a 1 nm thick Ti seed layer. FIG. 4C shows a high resolution TEM image of a Ti seed. The inset shows the convergent beam electron diffraction pattern of the seed confirming that it is a single crystal.

FIG. 5A shows a bright-field TEM image of an unseeded TiAl film annealed at 550° C. for 2 hours, showing no evidence of crystallization. The film crystallized only around 600° C. FIG. 5B shows a bright-field TEM image of a Ti-seeded TiAl film annealed at 550° C. for 2 hrs, showing clear evidence of crystallization. FIG. 5C shows heat flow versus temperature measured using differential scanning calorimetry (DSC) showing significant reduction in crystallization temperature for a Cu-seeded NiTi film.

### DETAILED DESCRIPTION

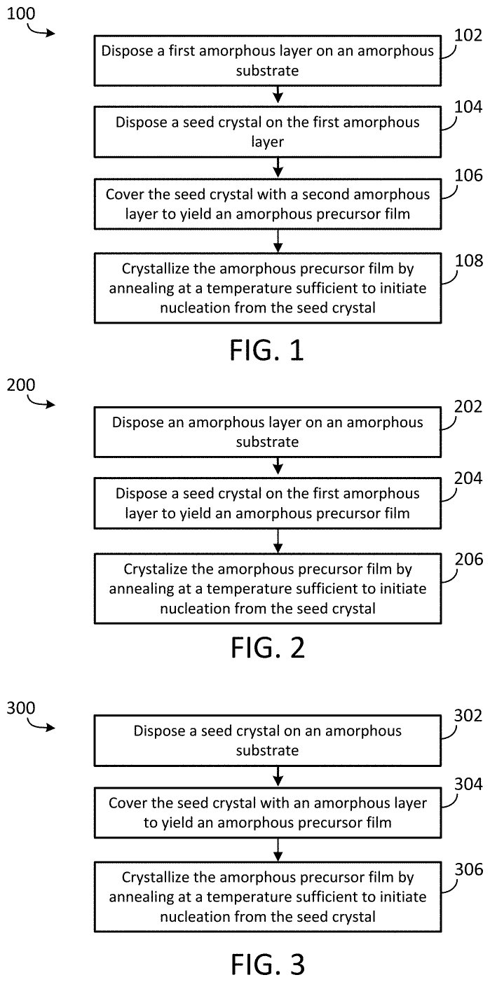

FIG. 1 is a flow chart describing operations in process 100 for generation of single crystal films from amorphous precursor films by nucleation and epitaxial or heteroepitaxial growth of a single grain from an embedded seed crystal. In 102, a first amorphous layer (e.g., an amorphous metallic alloy layer) is deposited on an amorphous substrate (e.g., by co-sputtering the constituent elements of the alloy) at room temperature (RT). In 104, a small (10-300 nm) seed crystal of an appropriate material is deposited on the amorphous layer at RT or elevated temperature (e.g., by sputtering through a patterned mask containing a single, nanometer-sized hole). The seed crystal can be limited to a single seed crystal. In 106, the seed crystal is covered by a second amorphous layer to form the amorphous precursor film comprising of the two amorphous layers and the embedded seed crystal. The seed crystal is preferably an effective nucleant able to reduce the crystallization temperature (T_{X}) by tens of degree Celsius. In 108, the amorphous precursor film is crystallized by annealing at a temperature (T_{X,S}) that is sufficient for the seed crystal to nucleate a single grain, which then grows to consume the film. If the seed crystal is chosen carefully, T_{X,S} is lower than the temperature needed for intrinsic grain nucleation in the unseeded regions of the film. Thus, crystallizing the film at T_{X,S} can ensure that no other grains are nucleated and the crystallized film is a single crystal. Since the crystallization temperature (T_{X}) of amorphous alloys is substantially lower than their melting temperature, this method allows synthesis of single crystal films at considerably lower temperatures (0.4-0.6 times the melting temperature or even lower) than other methods.

The seed crystal is chosen to allow epitaxial growth of the metallic alloy on it. The material for the seed crystal can be the metallic alloy itself or another material or combination of materials. Seed crystals that have a low misfit strain (εₘ) are likely to reduce the crystallization temperature more sharply. Process 100 provides a route to obtain single crystal films (e.g., tens to thousands of nanometers thick) over large areas (e.g., several square millimeters or even centimeters) on amorphous substrates via physical vapor deposition. This process is applicable to a broad range of metallic alloys, semiconductors and ceramics.

FIG. 2 depicts process 200 for generation of single crystal films from amorphous precursor films by nucleation and epitaxial or heteroepitaxial growth of a single grain from a seed crystal. In 202, an amorphous layer (e.g., an amorphous metallic alloy layer) is deposited on an amorphous substrate (e.g., by co-sputtering the constituent elements of the alloy) at room temperature (RT). In 204, a small (10-300 nm) seed crystal of an appropriate material is deposited on the amorphous layer at RT or elevated temperature (e.g., by sputtering through a patterned mask containing a single, nanometer-sized hole). The amorphous layer and the seed crystal together comprise the amorphous precursor film. The seed crystal is preferably an effective nucleant able to reduce the crystallization temperature (T_{X}) by tens of degree Celsius. In 206, the amorphous precursor film is crystallized by annealing at a temperature (T_{X,S}) that is sufficient for the seed crystal to nucleate a single grain, which then grows to consume the film. If the seed crystal is chosen carefully, T_{X,S} is lower than the temperature needed for intrinsic grain nucleation in the unseeded regions of the film. Thus, crystallizing the film at T_{X,S} can ensure that no other grains are nucleated and the crystallized film is a single crystal. Since the crystallization temperature (T_{X}) of amorphous alloys is substantially lower than their melting temperature, this method allows synthesis of single crystal films at considerably lower temperatures (0.4-0.6 times the melting temperature or even lower) than other methods.

The seed crystal is chosen to allow epitaxial growth of the metallic alloy on it. The material for the seed crystal can be the metallic alloy itself or other materials. Seed crystals that have a low misfit strain (εₘ) are likely to reduce the crystallization temperature more sharply. Process 200 provides a route to obtain single crystal films (e.g., tens to thousands of nanometers thick) over large areas (e.g., several square millimeters or even centimeters) on amorphous substrates via physical vapor deposition. This process is applicable to a broad range of metallic alloys, semiconductors and ceramics.

FIG. 3 depicts process 300 for generation of single crystal films from amorphous precursor films by nucleation and epitaxial or heteroepitaxial growth of a single grain from an embedded seed crystal. In 302, a small (10-300 nm) seed crystal of an appropriate material is deposited on an amorphous substrate at RT or elevated temperature (e.g., by sputtering through a patterned mask containing a single, nanometer-sized hole). In 304, the seed crystal is covered by an amorphous layer (e.g., an amorphous metallic alloy layer). The seed crystal is preferably an effective nucleant able to reduce the crystallization temperature (T_{X}) (e.g., by tens of degrees Celsius). The amorphous layer and the seed crystal together comprise the amorphous precursor film. In 306, the amorphous precursor film is crystallized by annealing at a temperature (T_{X,S}) that is sufficient for the seed crystal to nucleate a single grain, which then grows to consume the film. If the seed crystal is chosen carefully, T_{X,S} is lower than the temperature needed for intrinsic grain nucleation in the unseeded regions of the film. Thus, crystallizing the film at T_{X,S} can ensure that no other grains are nucleated and the crystallized film is a single crystal. Since the crystallization temperature (T_{X}) of amorphous alloys is substantially lower than their melting temperature, this method allows synthesis of single crystal films at considerably lower temperatures (0.4-0.6 times the melting temperature or even lower) than other methods.

The seed crystal is chosen to allow epitaxial growth of the metallic alloy on it. The material for the seed crystal can be the metallic alloy itself or other materials. Seed crystals that have a low misfit strain (εₘ) are likely to reduce the crystallization temperature more sharply. Process 300 provides a route to obtain single crystal films (e.g., tens to thousands of nanometers thick) over large areas (e.g., several square millimeters or even centimeters) on amorphous substrates via physical vapor deposition. This process is applicable to a broad range of metallic alloys, semiconductors and ceramics.

The far-from-equilibrium nature of the sputtering process (rapid quenching from the vapor phase) allows formation of metallic glasses, and a wide spectrum of metallic alloys can be deposited as amorphous films. In particular, ordered metallic alloys are suitable for growing thin films amorphously since their relatively high melting temperatures limit atomic diffusion at RT. In the absence of sufficient diffusion, their atomic ordering is lost, which results in the formation of amorphous structures.

### EXAMPLES

Two ordered binary alloys, TiAl and NiTi, were synthesized as amorphous films by co-sputtering. For simplicity, Ti₄₅Al₅₅ and Ni₅₀Ti₅₀ alloys, both of which lead to a single phase (γ-TiAl and austenitic NiTi) upon crystallization, were used. Thin crystalline seed layers (1-2 nm thick) of specific metals were deposited on the amorphous films, and isolated seed crystals were formed on the amorphous films via Volmer-Weber growth. Three seed crystals were deposited on each material system—Ti, Al and Ag for TiAl, and Cu, Cr and V for NiTi—all of which have a low εₘ (<5%). In particular, Al and V have extremely low εₘ (<1.5%) with γ-TiAl and austenitic NiTi, respectively.

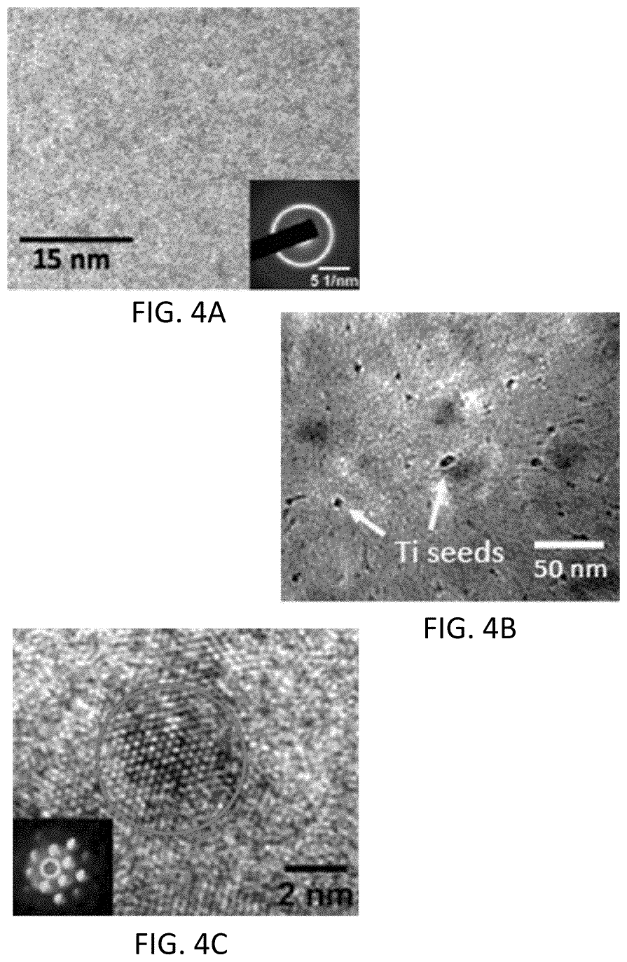

FIG. 4A shows a bright-field transmission electron microscopy (TEM) image of an amorphous TiAl film. The diffuse ring in the selected area electron diffraction pattern (inset) confirms the amorphous nature of the film. FIG. 4B shows a bright-field TEM image of a TiAl film embedded with Ti seed crystals. The Ti seeds formed spontaneously on deposition of a 1 nm thick Ti seed layer. FIG. 4C shows a high resolution TEM image of a Ti seed. The inset shows the convergent beam electron diffraction pattern of the seed confirming that it is a single crystal.

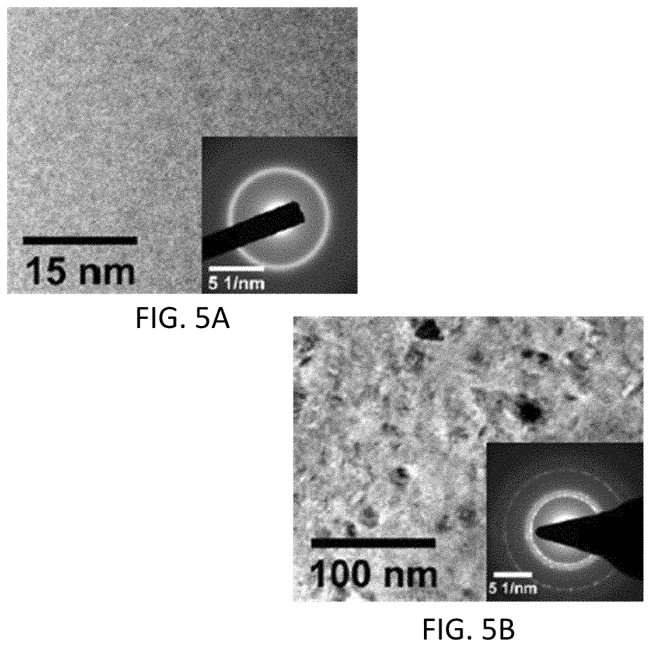

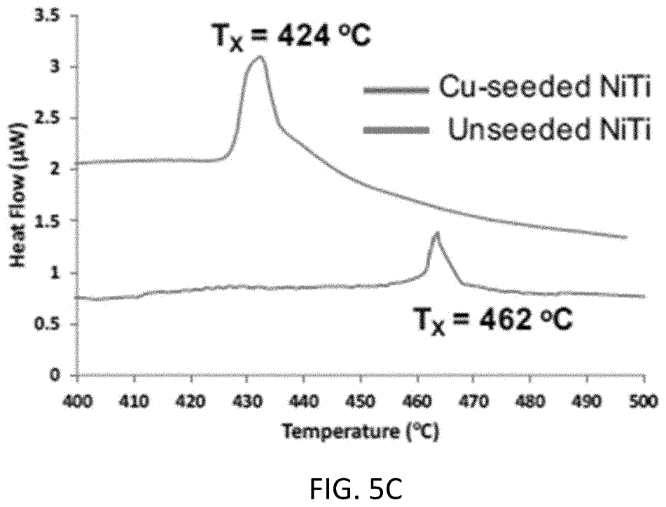

For TiAl, both Ti and Al (constituent elements of the alloy) form isolated crystals. For NiTi, seed crystals of Ti, Cr, and Cu were deposited. It was found that some of these seed crystals substantially reduce the crystallization temperature of the amorphous TiAl and NiTi films. FIG. 5A shows a bright-field TEM image of an unseeded TiAl film annealed at 550° C. for 2 hrs, showing no evidence of crystallization. The film crystallized only around 600° C. FIG. 5B shows a bright-field TEM image of a Ti-seeded TiAl film annealed at 550° C. for 2 hrs, showing clear evidence of crystallization. FIG. 5C shows heat flow versus temperature measured using differential scanning calorimetry (DSC) showing significant reduction in crystallization temperature for a Cu-seeded NiTi film.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A method of forming a single crystal film, the method comprising:
contacting a seed crystal with one or more amorphous metallic alloy layers to form an amorphous precursor film; and
annealing the amorphous precursor film to yield the single crystal film.

2. The method of claim 1, wherein contacting the seed crystal with the one or more amorphous metallic alloy layers comprises disposing the seed crystal on one of the one or more amorphous metallic alloy layers.

3. The method of claim 1, wherein contacting the seed crystal with the one or more amorphous metallic alloy layers comprises disposing one of the one or more amorphous metallic alloy layers on the seed crystal.

4. The method of claim 1, wherein contacting the seed crystal with the one or more amorphous metallic alloy layers comprises encapsulating the seed crystal between the amorphous metallic alloy layers.

5. The method of claim 1, wherein forming the one or more amorphous metallic alloy layers comprises co-depositing constituent elements of the metallic alloy.

6. The method of claim 5, wherein co-depositing the constituent elements comprises sputtering the constituent elements.

7. The method of claim 1, wherein contacting the seed crystal with the one or more amorphous metallic alloy layers comprises contacting a single seed crystal with the one or more amorphous metallic alloy layers.

8. The method of claim 1, wherein contacting the seed crystal with the one or more amorphous metallic alloy layers comprises sputtering the seed crystal through a patterned mask with a nanometer-sized opening.

9. The method of claim 1, wherein at least one of the one or more amorphous metallic alloy layers comprises TiAl.

10. The method of claim 9, wherein the crystallization of amorphous TiAl leads to the formation of γ-TiAl.

11. The method of claim 9, wherein the seed crystal comprises one or more of Ti, Al, TiAl and Ag.

12. The method of claim 1, wherein at least one of the one or more amorphous metallic alloy layers comprises NiTi.

13. The method of claim 12, wherein the crystallization of amorphous NiTi leads to the formation of austenitic NiTi.

14. The method of claim 12, wherein the seed crystal comprises one or more of NiTi, Cu, Cr, Fe, W, Nb and V.

15. The method of claim 1, wherein the seed crystal has a misfit strain (εₘ) with the amorphous metallic alloy layer of less than 10%.

16. The method of claim 1, further comprising forming at least one of the one or more amorphous metallic alloy layer at room temperature.

17. The method of claim 1, wherein the seed crystal lowers the crystallization temperature of the one or more amorphous metallic alloy layers.

18. The method of claim 1, wherein annealing the amorphous precursor film comprises heating the amorphous precursor film below 0.6 Tₘ, where Tₘ represents the melting temperature of at least one of the one or more amorphous metallic alloy layers.
